(19) United States
(12) Patent Application Publication
(10) Pub. No.: US 2025/0318121 A1
(43) Pub. Date: Oct. 9, 2025

(54) METHOD OF MANUFACTURING A MEMORY DEVICE

(71) Applicant: SK hynix Inc., Icheon-si Gyeonggi-do (KR)

(72) Inventor: Jae Ho KIM, Icheon-si Gyeonggi-do (KR)

(73) Assignee: SK hynix Inc., Icheon-si Gyeonggi-do (KR)

(21) Appl. No.: 18/777,946

(22) Filed: Jul. 19, 2024

(30) Foreign Application Priority Data
Apr. 4, 2024 (KR) 10-2024-0045953

(51) Int. Cl. H10B 43/27

(52) U.S. Cl. CPC H10B 43/27

(57) ABSTRACT

A method of manufacturing a memory device according to an embodiment of the present disclosure includes forming first openings passing through a first preliminary stacked structure, forming sacrificial pillars filling the first openings, forming a second preliminary stacked structure over the first preliminary stacked structure and the sacrificial pillars, forming first channel holes passing through the first preliminary stacked structure and the second preliminary stacked structure by removing a portion of the second preliminary stacked structure and the sacrificial pillars, and forming cell plugs in the first channel holes.

### CROSS-REFERENCE TO RELATED APPLICATION

The present application claims priority under 35 U.S.C. § 119(a) to Korean patent application number 10-2024-0045953 filed on Apr. 4, 2024, in the Korean Intellectual Property Office, the entire contents of which application is incorporated herein by reference.

### BACKGROUND

### 1. Technical Field

The present disclosure generally relates to a method of manufacturing a memory device, and more particularly, to a method of manufacturing a memory device including a memory block having a three-dimensional structure.

### 2. Related Art

A memory device may include a non-volatile memory device that retains stored data even in the absence of power supply. Non-volatile memory devices may be divided into a two-dimensional structure or a three-dimensional structure depending on arrangements of memory cells. Memory cells of a non-volatile memory device having a two-dimensional structure may be arranged in a single layer on a substrate. Memory cells of a non- volatile memory device having a three-dimensional structure may be stacked in a vertical direction to the substrate. Since an integration density of the non-volatile memory device having the three-dimensional structure is greater than that of the non- volatile memory device having the two-dimensional structure, electronic devices using three-dimensionally structured non- volatile memory devices have been increasing.

### SUMMARY

According to an embodiment, a method of manufacturing a memory device may include forming first openings passing through a first preliminary stacked structure, forming sacrificial pillars filling the first openings, forming a second preliminary stacked structure over the first preliminary stacked structure and the sacrificial pillars, forming first channel holes passing through the first preliminary stacked structure and the second preliminary stacked structure by removing a portion of the second preliminary stacked structure and the sacrificial pillars, and forming cell plugs in the first channel holes.

### BRIEF DESCRIPTION OF THE DRAWINGS

FIG. 1 is a diagram illustrating an example of a memory device according to an embodiment of the present disclosure;

FIG. 2 is a schematic view illustrating a memory device according to an embodiment of the present disclosure;

FIG. 3 is a cross-sectional diagram showing a memory device according to an embodiment of the present disclosure;

FIGS. 4A and 4B are plan views illustrating the layout of a memory device according to a first embodiment of the present disclosure;

FIGS. 5A and 5B are plan views illustrating the layout of a memory device according to a second embodiment of the present disclosure;

FIGS. 6, 7A, 7B, 7C, 8A, 8B, 8C, 9, 10A, 10B, 10C, and 11, 12, 13 and 14 are diagrams illustrating a method of manufacturing a memory device according to an embodiment of the present disclosure;

FIG. 15 is a diagram illustrating a memory card system to which a memory device according to the present disclosure is applied; and

FIG. 16 is a diagram illustrating a solid state drive

(SSD) to which a memory device according to the present disclosure is applied.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Hereinafter, various embodiments of the present disclosure will be described in detail with reference to the accompanying drawings in order for those skilled in the art to be able to readily implement the technical spirit of the present disclosure.

According to various embodiments of the present disclosure, a method of manufacturing a memory device capable of reducing defects of cell plugs may be provided.

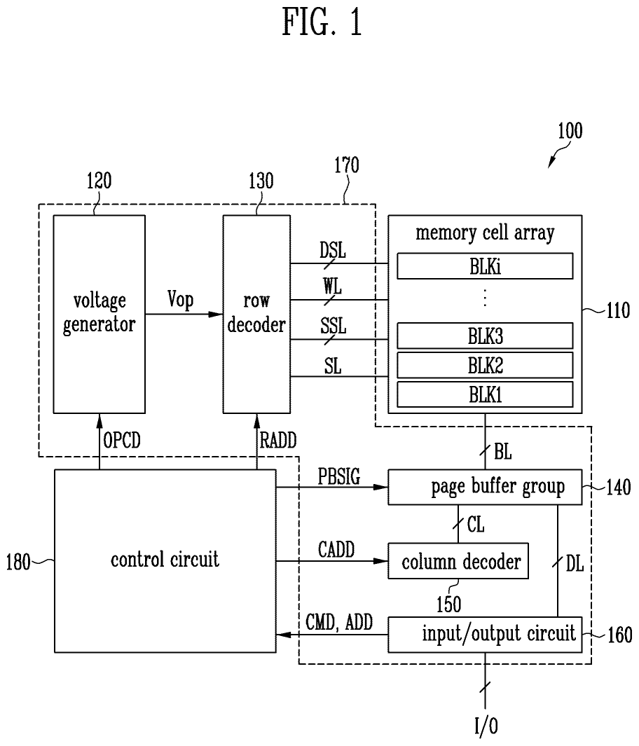

FIG. 1 is a diagram illustrating a memory device 100 according to an embodiment of the present disclosure.

Referring to FIG. 1, the memory device 100 may include a memory cell array 110, a peripheral circuit 170, and a control circuit 180.

The memory cell array 110 may include first to ith memory blocks BLK1 to BLKi. Each of the first to ith memory blocks BLK1 to BLKi may include memory cells which store data. Drain select lines DSL, word lines WL, source select lines SSL, and a source line SL may be coupled to each of the first to ith memory blocks BLK1 to BLKi, and bit lines BL may be commonly coupled to the first to ith memory blocks BLK1 to BLKi.

The first to ith memory blocks BLK1 to BLKi may have a three-dimensional structure. Each of the three-dimensionally structured memory blocks may include memory cells which are stacked in a perpendicular direction to a substrate.

The memory cells may include 1-bit data or two or more bits of data according to a program method. For example, a method of storing one bit in a single memory cell is referred to as a single-level cell method, and a method of storing two bits of data is referred to as a multi-level cell. A method of storing three bits of data in a single memory cell is referred to as a triple-level cell method. A method of storing four bits of data is referred to as a quad level cell method. Further, five or more bits of data may be stored in a single memory cell.

The peripheral circuit 170 may include a program operation for storing data in the memory cell array 110, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop applied to perform a program operation, a read operation, or an erase operation in response to an operating code OPCD. For example, the voltage generator 120 may be configured to generate program voltages, turn-on voltages, turn-off voltages, negative voltages, precharge voltages, verify voltages, read voltages, pass voltages, or erase voltages in response to the operating code OPCD. The operating voltages Vop generated by the voltage generator 120 may be applied to the drain select lines DSL, the word lines WL, the source select lines SSL, and the source line SL of a selected memory block through the row decoder 130.

Program voltages may be applied to a selected word line among the word lines WL during a program operation and may be used to increase threshold voltages of memory cells coupled to the selected word line. Turn-on voltages may be applied to the drain select lines DSL or the source select lines SSL and used to turn on drain select transistors or source select transistors. Turn-off voltages may be applied to the drain select lines DSL or the source select lines SSL and may be used to turn on the drain select transistors or the source select transistors. For example, a turn-off voltage may be set to 0 V. Precharge voltages may be greater than 0 V and be applied to bit lines during a read operation. Verify voltages may be used during a verify operation for determining whether threshold voltages of selected memory cells are increased to a target level. The verify voltages may be set to various levels depending on the target level and applied to a selected word line.

Read voltages may be applied to the selected word line during a read operation of selected memory cells. For example, the read voltages may be set to various levels according to a program method of the selected memory cells. Pass voltages may be applied to unselected word lines, among the word lines WL, during a program or read and may be used to turn on memory cells coupled to the unselected word lines. Erase voltages may be used during an erase operation for erasing memory cells included in the selected memory block and may be applied to the source line SL.

The row decoder 130 may be configured to apply the operating voltages Vop to the drain select lines DSL, the word lines WL, the source select lines SSL, and the source line SL which are coupled to the selected memory block depending on a row address RADD. For example, the row decoder 130 may be coupled to the voltage generator 120 through global lines and to the first to ith memory blocks BLK1 to BLKi through the drain select lines DSL, the word lines WL, the source select lines SSL, and the source line SL.

The page buffer group 140 may include page buffers (not shown) which are coupled to the first to ith memory blocks BLK1 to BLKi, respectively. Each of the page buffers (not shown) may be coupled to the first to ith memory blocks BLK1 to BLKi through the bit lines BL. During a read operation, each of the page buffers (not shown) may sense currents or voltages in bit lines which vary depending on threshold voltages of selected memory cells in response to page buffer control signals PBSIG, and may store sensed data.

The column decoder 150 may be configured to transfer data between the page buffer group 140 and the input/output circuit 160 in response to a column address CADD. For example, the column decoder 150 may be coupled to the page buffer group 140 through column lines CL and transfer enable signals through the column lines CL. The page buffers (not shown) included in the page buffer group 140 may receive or output data through data lines DL in response to the enable signals.

The input/output circuit 160 may receive or output a command CMD, an address ADD and data through input/output lines I/O. For example, the input/output circuit 160 may transfer the command CMD and the address ADD, which are received from an external device through the input/output lines I/O, to the control circuit 180, and may transfer the data, which is received from the external controller through the input/output lines I/O, to the page buffer group 140. Alternatively, the input/output circuit 160 may output the data, which is transferred from the page buffer group 140, to the external controller through the input/output lines I/O.

The control circuit 180 may output at least one of the operating code OPCD, the row address RADD, the page buffer control signals PBSIG, and the column address CADD in response to the command CMD and the address ADD. For example, when the command CMD which is input to the control circuit 180 corresponds to a program operation, the control circuit 180 may control the peripheral circuit 170 to perform a program operation of the selected memory block by the address ADD. When the control circuit 180 corresponds to a read operation, the control circuit 180 may control the peripheral circuit 170 to perform a read operation of the selected memory block by the address and output the read data. When the command CMD which is input to the control circuit 180 corresponds to an erase operation, the control circuit 180 may control the peripheral circuit 170 to perform the erase operation of the selected memory block.

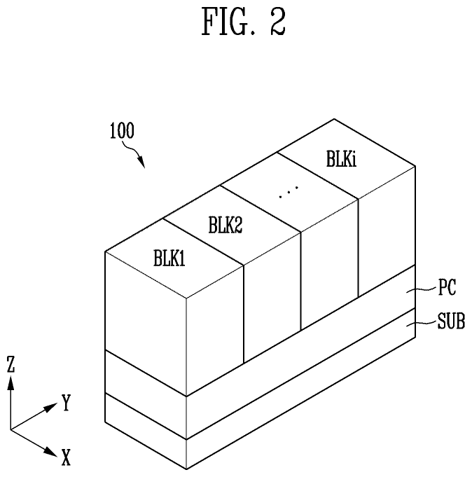

FIG. 2 is a schematic diagram illustrating the memory device 100 according to an embodiment of the present disclosure.

Referring to FIG. 2, the memory device 100 may include a peripheral circuit structure PC and the first to ith memory blocks BLK1 to BLKi. The first to ith memory blocks BLK1 to BLKi may overlap the peripheral circuit structure PC.

A substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin film formed by using a selective epitaxial growth technique.

The peripheral circuit structure PC may include a row decoder 130, a column decoder 150, a page buffer group 140, and a control circuit 180 which constitute a circuit for controlling operations of the first to ith memory blocks BLK1 to BLKi. For example, the peripheral circuit structure PC may include an NMOS transistor, a PMOS transistor, a resistor, and a capacitor which are electrically coupled to the first to ith memory blocks BLK1 to BLKi. The peripheral circuit structure PC may be arranged between the substrate SUB and the first to ith memory blocks BLK1 to BLKi.

Each of the first to ith memory blocks BLK1 to BLKi may include a source structure, bit lines, cell strings electrically coupled between the source structure and the bit lines, word lines electrically coupled to the cell strings, and select lines electrically coupled to the cell strings. Each of the cell strings may include memory cells and select transistors that are coupled in series by a cell plug. Each of the select lines may serve as a gate electrode of a corresponding one of the select transistors. Each of the word lines may serve as a gate electrode of a corresponding one of the memory cells.

In another embodiment, the substrate SUB, the peripheral circuit structure PC, and the first to ith memory blocks BLK1 to BLKi may be stacked in a reverse order to the order shown in FIG. 2. For example, the peripheral circuit structure PC may be disposed over the first to ith memory blocks BLK1 to BLKi.

In another embodiment, contrary to FIG. 2, the peripheral circuit structure PC may be disposed over some areas of the substrate SUB which do not overlap the first to ith memory blocks BLK1 to BLKi. For example, the peripheral circuit structure PC and the first to ith memory blocks BLK1 to BLKi may be respectively disposed in areas of the substrate SUB which do not overlap each other.

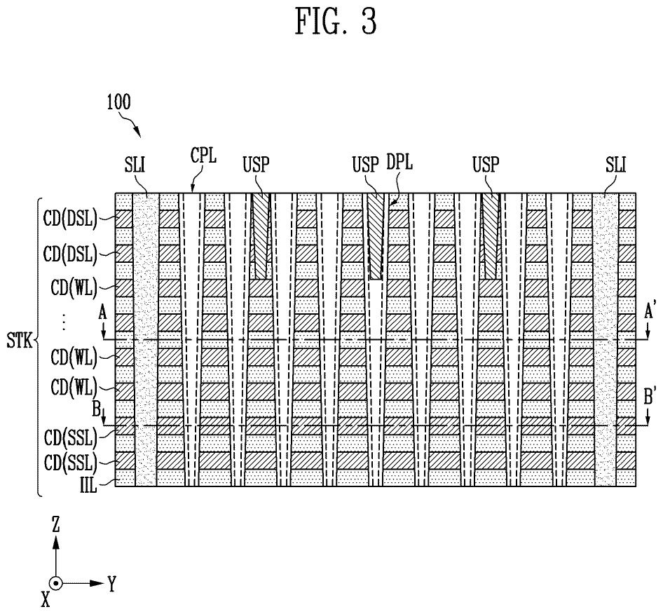

FIG. 3 is a cross-sectional diagram the memory device 10 according to an embodiment of the present disclosure.

FIG. 3 shows a cross section of any one of the first to ith memory blocks BLK1 to BLKi, which are shown in FIGS. 1 and 2, taken in a vertical direction to an X direction. In an embodiment, the vertical direction being the Z direction. The peripheral circuit structure PC and the substrate SUB of FIG. 2 are not shown in FIG. 3.

The memory device 100 may include a stacked structure STK. The stacked structure STK may include conductive layers CD and interlayer insulating layers IIL which are stacked alternately with each other in a Z axis. The conductive layers CD may include drain select lines DSL, word lines WL, and source select lines SSL. As shown in FIG. 3, the memory device 100 may include the drain select lines DSL in two layers and the source select lines SSL in two layers. However, the number of layers on which the drain select lines DSL are formed and the number of layers on which the source select lines SSL are formed might not be limited thereto. For example, the memory device 100 may include the drain select lines DSL in one or at least three layers, or the source select lines SSL in one or at least three layers.

The memory device 100 may include slits SLI which pass through the stacked structure STK. Each of the slits SLI may extend in a Z direction and the X direction. The slits SLI may separate neighboring memory blocks from each other. For example, one memory block shown in FIG. 3 may be insulated from neighboring memory blocks in the Y direction by the slits SLI. The conductive layers CD may be separated from the conductive layers CD of the neighboring memory blocks by the slits SLI.

An upper isolation structure USP may partially pass through the stacked structure STK. The upper isolation structure USP may have a depth (e.g., a length in the Z direction) such that the upper isolation structure USP may pass through the drain select lines DSL and might not pass through the word lines WL. For example, the upper isolation structure USP may be deep enough to pass through the first and second conductive layers CD from the top among the conductive layers CD. The upper isolation structure USP might not contact the word line WL, or might not completely pass through the word line WL even when the upper isolation structure USP contacts the word line WL. The upper isolation structure USP may include an insulating material (e.g., an oxide layer).

The drain select lines DSL may be insulated from each other by the upper isolation structure USP. For example, within any one memory block, the uppermost conductive layer CD may be divided into four drain select lines DSL by three upper isolation structures USP. In addition, within any one memory block, the second conductive layer CD from the top may be divided into four drain select lines DSL by three upper isolation structures USP.

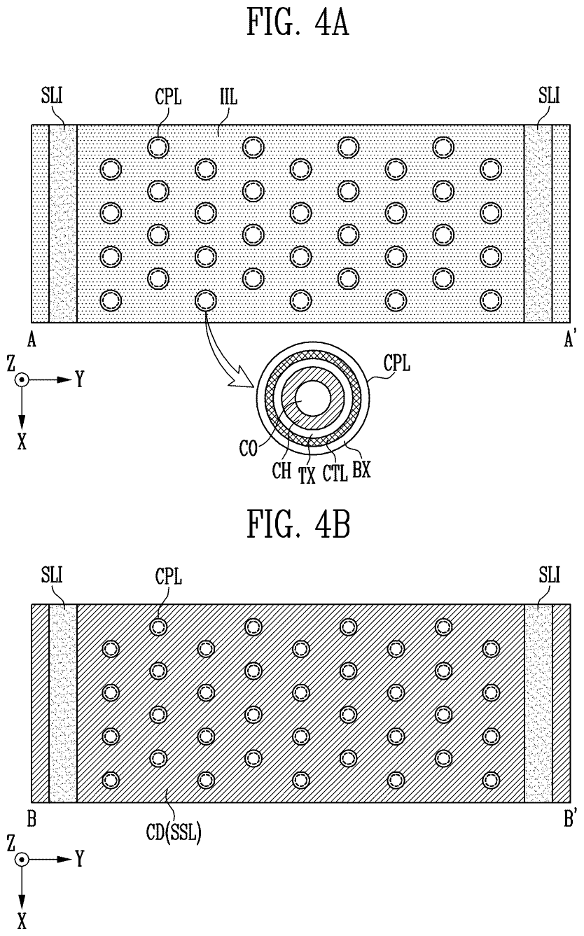

Cell plugs CPL may be located in the stacked structure STK. Each of the cell plugs CPL may extend in the Z direction. The cell plugs CPL may pass through the stacked structure STK. The cell plugs CPL may be located between the slits SLI. Configurations included in the cell plugs CPL will be described below with reference to FIG. 4A.

Some of the upper isolation structures USP may be formed between the cell plugs CPL. In addition, other upper isolation structures USP may overlap the cell plugs CPL. The cell plugs CPL which overlap the upper isolation structure USP may be referred to as dummy cell plugs DPL. In the present disclosure, it may be understood that the cell plugs CPL include the dummy cell plugs DPL. Unlike the cell plugs CPL, the dummy cell plugs DPL might not operate as select transistors or memory cell transistors. The dummy cell plugs DPL may include the same configurations as the cell plugs CPL.

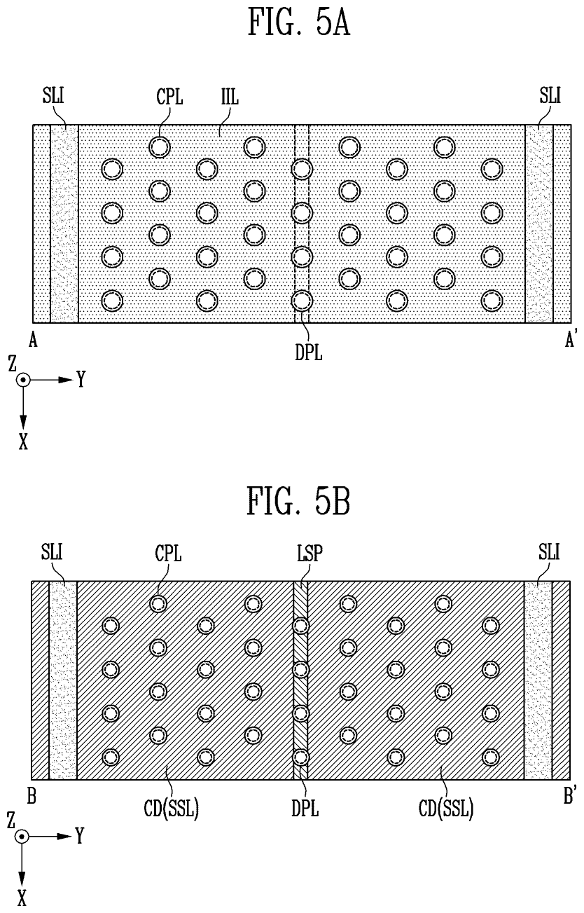

Though not shown in the cross-section of FIG. 3, the memory device 100 may further include a lower isolation structure. The memory device 100 which further includes the lower isolation structure will be described below with reference to FIGS. 5A and 5B.

FIGS. 4A and 4B are plan views showing the layout of a memory device according to a first embodiment of the present disclosure. FIG. 4A is a plan view showing a cross section A-A′ of FIG. 3. FIG. 4B is a plan view showing a cross section B-B′ of FIG. 3. The configurations described in association with FIG. 3, among the configurations shown in FIGS. 4A and 4B, may be briefly described or might not be described.

Referring to FIG. 4A, the cell plugs CPL may be arranged in a plurality of columns. Each of the columns may include the cell plugs CPL which are spaced apart from each other in an X axis. The plurality of columns may be spaced apart from each other in a Y axis. The center of the cell plugs CPL included in odd columns and the center of the cell plugs CPL included in even columns may be offset from each other. For example, neighboring cell plugs CPL in a Y direction may be arranged in a zigzag format. FIG. 4A illustrates an embodiment in which the cell plugs CPL are arranged in nine columns between neighboring slits SLI in the Y direction. However, the present disclosure is not limited thereto. For example, the cell plugs CPL may be arranged in eight or fewer columns, or ten or more columns (e.g., 19 columns).

The cell plugs CPL may include a blocking layer BX having a cylindrical shape, a charge trap layer CTL formed on an inner wall of the blocking layer BX, a tunnel isolation layer TX formed on an inner wall of the charge trap layer CTL, a channel layer CH formed on an inner wall of the tunnel isolation layer TX, a core pillar CO having a cylindrical shape in an area surrounded by the channel layer CH. Each of the blocking layer BX and the tunnel isolation layer TX may include an oxide layer (e.g., a silicon oxide layer). The charge trap layer CTL may include a nitride layer. The channel layer CH may include a doped silicon layer. The core pillar CO may include an insulating layer or a conductive layer. Each of the blocking layer BX, the charge trap layer CTL, the tunnel isolation layer TX, the channel layer CH, and the core pillar CO formed in the cell plug CPL may extend in a vertical direction Z.

Referring to FIGS. 4A and 4B, each of the cell plugs CPL may have an area varying depending on a location in the Z direction. For example, a planar area of each of the cell plugs CPL may increase in the Z direction.

In addition, some of the cell plugs CPL as shown in FIG. 4A and 4B may be the dummy cell plugs CPL. For example, the cell plugs CPL which overlap the upper isolation structure USP as shown in FIG. 3 may correspond to the dummy cell plugs DPL.

FIGS. 5A and 5B are plan views illustrating the layout of the memory device 100 according to a second embodiment of the present disclosure. FIG. 5A is a plan view showing a cross section A-A′ of FIG. 3. FIG. 5B is a plan view showing a cross section B-B′ of FIG. 3. Some of the configurations shown in FIGS. 5A and 5B which, have been described above in association with FIGS. 3, 4A, and 4B, may be briefly described, or might not be described.

Referring to FIGS. 5A and 5B, the memory device 100 may include a lower isolation structure LSP. The lower isolation structure LSP may partially pass through the stacked structure STK. The lower isolation structure LSP may be formed at a position where the lower isolation structure LSP passes through the source select lines SSL and does not pass through the word lines WL. For example, the lower isolation structure LSP may pass through the first and second conductive layers CD from the bottom among the conductive layers CD shown in FIG. 3. The lower isolation structure LSP might not contact the word line WL, or might not completely pass through the word line WL even when the lower isolation structure LSP contacts the word line WL. The lower isolation structure LSP may include an insulating material (e.g., an oxide layer).

The source select lines SSL may be insulated from each other by the lower isolation structure LSP. For example, the conductive layer CD of FIG. 5B may be divided into two source select lines SSL by the lower isolation structure LSP. The lower isolation structure LSP may extend in the X direction and the source select lines SSL may be adjacent to each other in the Y direction.

The lower isolation structure LSP may overlap the cell plugs CPL. The cell plugs CPL which overlap the lower isolation structure LSP may be referred to as the dummy cell plugs DPL. The lower isolation structure LSP may overlap the upper isolation structure USP of FIG. 3. For example, the upper isolation structure USP may overlap the lower isolation structure LSP so as to reduce the number of dummy cell plugs DPL.

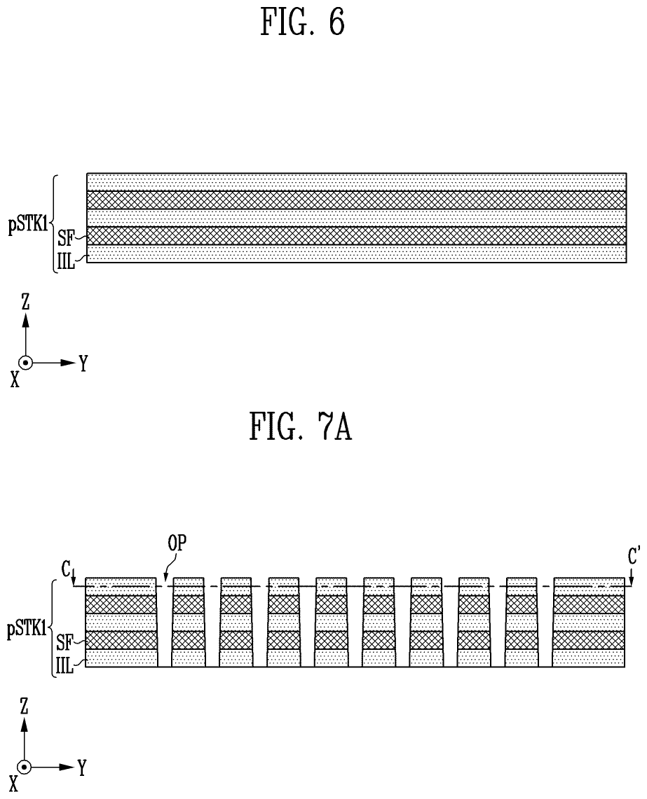

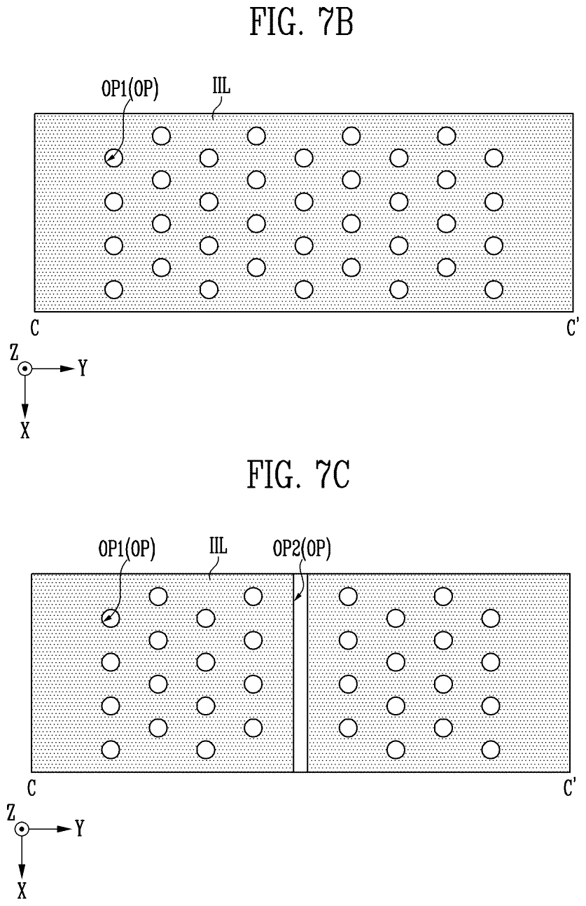

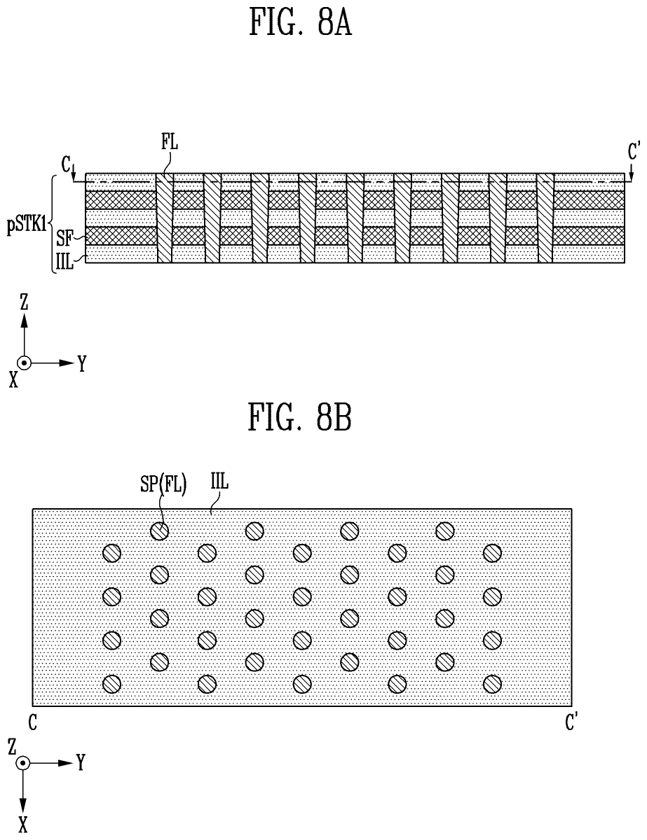

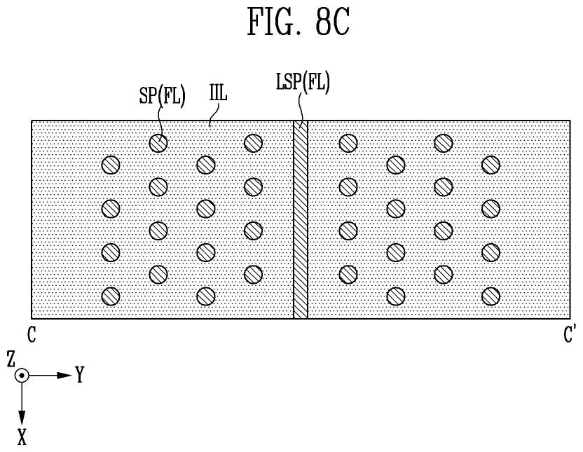

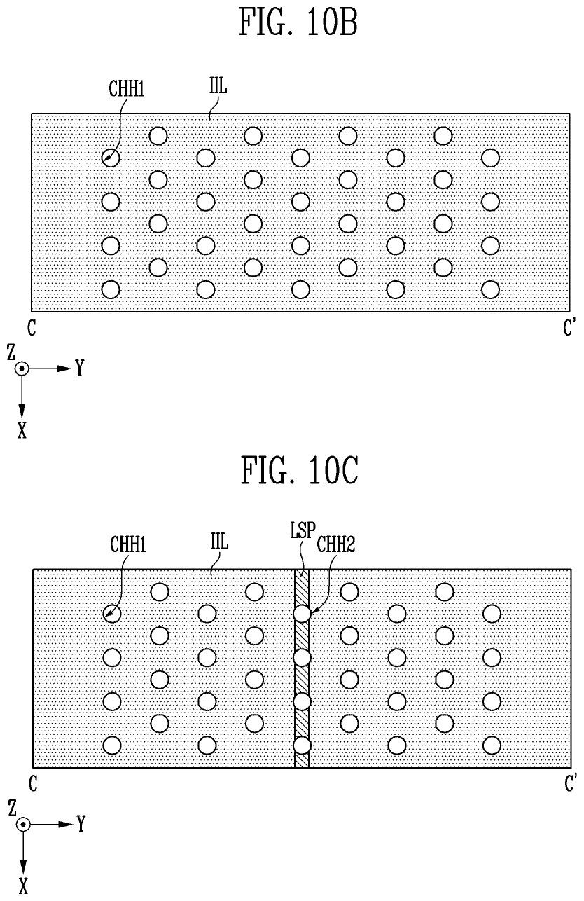

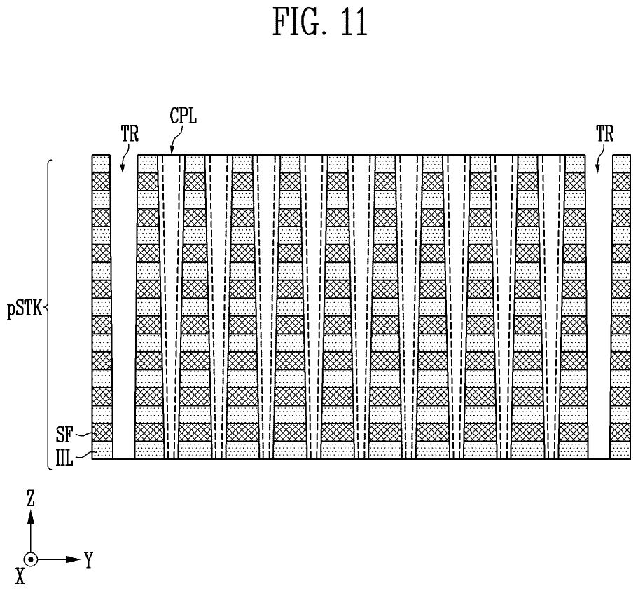

FIGS. 6, 7A to 7C, 8A to 8C, 9, 10A to 10C, and 11 to 14 are diagrams illustrating a method of manufacturing a memory device according to an embodiment of the present disclosure. FIGS. 7B, 8B, and 10B show the first embodiment of the present disclosure. FIGS. 7C, 8C, and 10C show the second embodiment of the present disclosure. FIGS. 7B and 7C are plan views showing a cross section C-C′ of FIG. 7A. FIGS. 8B and 8C are plan views showing a cross section C-C′ of FIG. 8A. FIGS. 10B and 10C are plan views showing a cross section C-C′ of FIG. 10A.

Referring to FIG. 6, a first preliminary stacked structure pSTK1 may be formed. The first preliminary stacked structure pSTK1 may include at least one interlayer insulating layer IIL and at least one sacrificial layer SF. For example, the first preliminary stacked structure pSTK1 may include the interlayer insulating layers IIL stacked in three layers and the sacrificial layers SF stacked in two layers which are interposed between the interlayer insulating layers IIL. The number of layers on which the sacrificial layers SF included in the first preliminary stacked structure pSTK1 as shown in FIG. 6 are formed may correspond to the number of layers on which the source select lines SSL of FIG. 3 are formed. In other words, the height of the first preliminary stacked structure pSTK1 may be determined based on the number of source select lines SSL included in the memory device 100. The first preliminary stacked structure pSTK1 may have a smaller height than the stacked structure STK shown in FIG. 3.

Each interlayer insulating layer IIL may include an insulating material. For example, the interlayer insulating layers IIL may include an oxide layer (e.g., a silicon oxide layer). The sacrificial layers SF may include a material which is selectively removed during subsequent processes. The sacrificial layers SF may have a different etch selectivity from the interlayer insulating layers IIL. For example, the sacrificial layers layer SF may include a nitride layer. In the present disclosure, the interlayer insulating layer IIL included in the first preliminary stacked structure pSTK1 may be referred to as a first material layer, and the sacrificial layer SF included in the first preliminary stacked structure pSTK1 may be referred to as a second material layer.

Referring to FIG. 7A, openings OP may pass through the first preliminary stacked structure pSTK1. The openings OP may pass through the interlayer insulating layers IIL and the sacrificial layers SF included in the first preliminary stacked structure pSTK1. A lower structure (e.g., a substrate) which is located under the first preliminary stacked structure pSTK1 may be exposed through the openings OP. FIG. 7B illustrates the shape and arrangement of the openings OP in the memory device 100 according to the first embodiment. FIG. 7C illustrates the shape and arrangement of the openings OP in the memory device 100 according to the second embodiment.

Referring to FIG. 7B, the openings OP of FIG. 7A may include first openings OP1. The first openings OP1 may have a shape of a hole. The first openings OP1 may have a circular or elliptical plane. For example, in an embodiment, the first openings OP1 may have a circular or elliptical plane and a depth opposite the Z direction into the first and/or second preliminary stacked structures pSTK1 and pSTk2 to provide a shape of a hole as shown in, for example, FIGS. 7A, 7B, and 7C.

The first openings OP1 may be arranged to correspond to the arrangement of the cell plugs CPL shown in FIG. 4B. For example, the first openings OP1 may be arranged in a plurality of columns. Each of the columns may include the first openings OP1 which are spaced apart from each other in the X axis. The plurality of columns may be spaced apart from each other in the Y axis. The center of the first openings OP1 included in odd columns may be offset from the center of the first openings OP1 included in even columns. In other words, the location of the first openings OP1 may correspond to a location at which the cell plugs CPL are arranged.

Referring to FIG. 7C, the openings OP of FIG. 7A may include the first openings OP1 and a second opening OP2. The first openings OP1 may have a shape of a hole. The first openings OP1 may have a circular or elliptical plane. The second opening OP2 may have a line shape. The second opening OP2 may extend in the X direction. The second opening OP2 may have a rectangular plane. The first openings OP1 and the second opening OP2 may be formed simultaneously. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

The first openings OP1 may be arranged to correspond to the arrangement of the cell plugs CPL except for the dummy cell plugs DPL as shown in FIG. 5B. In addition, the second opening OP2 may be formed at a location corresponding to the lower isolation structure LSP of FIG. 5B. For example, the first openings OP1 arranged in a plurality of columns may be separated from the second opening OP2 in a Y direction or an opposite direction to the Y direction. According to an embodiment, the first openings OP1 may be symmetrical with respect to each other on the basis of the second opening OP2.

The location of the first openings OP1 may correspond to a location where some of the cell plugs CPL to be formed later are located. The location of the second opening OP2 may correspond to a location of the lower isolation structure LSP to be formed later.

Referring to FIG. 8A, filling layers FL which fill the openings OP may be formed. The filling layers FL may include an insulating material (e.g., an oxide layer). For example, a deposition process of depositing an insulating layer onto the entire structure of FIG. 7A may be performed, and a planarizing process for removing a portion of the insulating layer which is located on the first preliminary stacked structure pSTK1 may be performed. The insulating layer remaining in the openings OP after the deposition process and the planarizing process may be referred to as the filling layers FL. FIG. 8B illustrates the shape and arrangement of the filling layers FL in the memory device 100 according to the first embodiment. FIG. 8C illustrates the shape and arrangement of the filling layers FL in the memory device 100 according to the second embodiment.

Referring to FIG. 8B, the filling layers FL may include sacrificial pillars SP. The sacrificial pillars SP may fill the first openings OP1, respectively. Each of the sacrificial pillars SP may be formed in each of the first openings OP1. The sacrificial pillars SP may have a cylindrical or elliptical shape.

Referring to FIG. 8C, the filling layers FL may include the sacrificial pillars SP and the lower isolation structure LSP. The sacrificial pillars SP may fill the first openings OP1, respectively. The lower isolation structure LSP may fill the second opening OP2. The lower isolation structure LSP may be formed in the second opening OP2. The lower isolation structure LSP may have a shape of a plate which extends in the Z direction and the X direction. The sacrificial pillars SP and the lower isolation structure LSP may include the same material. The sacrificial pillars SP and the lower isolation structure LSP may be formed simultaneously.

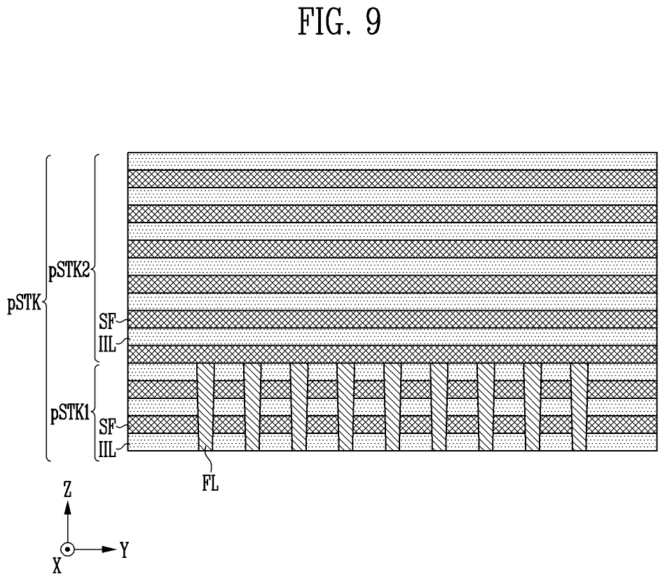

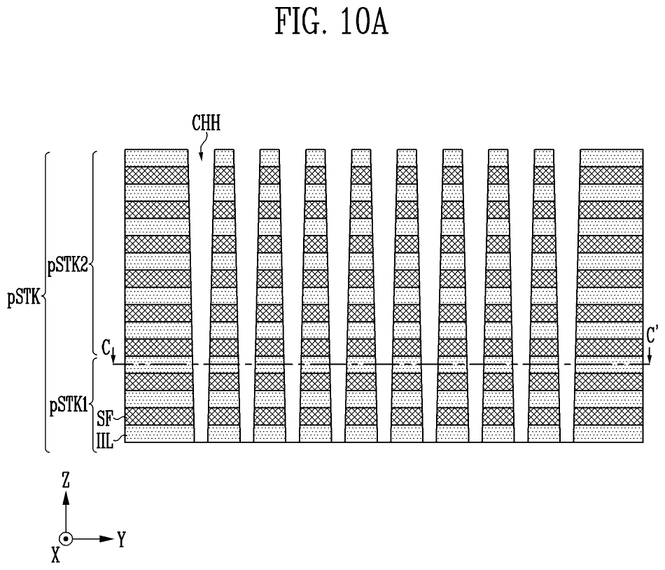

Referring to FIG. 9, a second preliminary stacked structure pSTK2 may be formed on the first preliminary stacked structure pSTK1. The second preliminary stacked structure pSTK2 may cover the first preliminary stacked structure pSTK1 and the filling layers FL. The second preliminary stacked structure pSTK2 may include the interlayer insulating layers IIL and the sacrificial layers SF. The number of layers on which the sacrificial layers SF included in the second preliminary stacked structure pSTK2 are formed as shown in FIG. 9 may correspond to the number of layers on which the word lines WL and the drain select lines DSL of FIG. 3 are formed. The first preliminary stacked structure pSTK1 and the second preliminary stacked structure pSTK2 may be collectively referred to as a preliminary stacked structure pSTK. The number of layers of the preliminary stacked structure pSTK may correspond to the number of layers of the stacked structure STK.

The interlayer insulating layers IIL of the second preliminary stacked structure pSTK2 may include the same material as the interlayer insulating layers IIL of the first preliminary stacked structure pSTK1. The sacrificial layers SF of the second preliminary stacked structure pSTK2 may include the same material as the sacrificial layers SF of the first preliminary stacked structure pSTK1. In the present disclosure, the interlayer insulating layer IIL included in the second preliminary stacked structure pSTK2 may be referred to as a third material layer, and the sacrificial layer SF included in the second preliminary stacked structure pSTK2 may be referred to as a fourth material layer.

Referring to FIG. 10A, channel holes CHH may pass through the first preliminary stacked structure pSTK1 and the second preliminary stacked structure pSTK2. The channel holes CHH may pass through the interlayer insulating layers IIL and the sacrificial layers SF included in the preliminary stacked structure pSTK. The height of the channel holes CHH may be greater than or equal to that of the preliminary stacked structure pSTK.

The channel holes CHH may be formed by removing a portion of the second preliminary stacked structure pSTK2 and at least a portion of the filling layers FL. For example, an area of the second preliminary stacked structure pSTK2 which overlaps at least the portion of the filling layers FL may be etched. As the second preliminary stacked structure pSTK2 is partially etched, at least portions of upper surfaces of the filling layers FL may be exposed. Subsequently, at least portions of the exposed filling layers FL may be etched. As a result, the channel holes CHH may be formed.

In an embodiment, the channel holes CHH may have a tapered cross-section which gradually decrease toward the bottom (e.g., in an opposite direction to the Z direction). In an embodiment, sidewalls of the channel holes CHH may be smoothly extended curved surfaces. For example, the sidewalls of the channel holes CHH might not have irregularities. That is, in an embodiment, at a level corresponding to an interface between the first preliminary stacked structure pSTK1 and the second preliminary stacked structure pSTK2, the width of the channel holes CHH might not be drastically changed.

FIG. 10B illustrates the channel holes CHH included in the memory device 100 according to the first embodiment. FIG. 10C illustrates the channel holes CHH included in the memory device 100 according to the second embodiment.

Referring to FIG. 10B, the channel holes CHH may include first channel holes CHH1. The first channel holes CHH1 may be formed by removing a portion of the second preliminary stacked structure pSTK2 and the sacrificial pillars SP. For example, upper surfaces of the sacrificial pillars SP may be exposed by etching a portion of the second preliminary stacked structure pSTK2 (e.g., areas thereof overlapping the sacrificial pillars SP). Subsequently, the exposed sacrificial pillars SP may be removed. The areas from which the second preliminary stacked structure pSTK2 are etched and the areas from which the sacrificial pillars SP are removed may correspond to the first channel holes CHH1.

As the sacrificial pillars SP are etched, the sacrificial pillars SP might not remain. Therefore, the first channel holes CHH1 may include the first openings OP1, respectively. In addition, an inner surface of the first preliminary stacked structure pSTK1 may be exposed through the first channel holes CHH1.

Compared to when the sacrificial pillars SP are not formed in the first preliminary stacked structure pSTK1, defects in the first channel holes CHH1, in an embodiment, may be reduced when the first channel holes CHH1 are formed with the sacrificial pillars SP formed in the first preliminary stacked structure pSTK1. For example, the sacrificial pillars SP may be more easily etched than the interlayer insulating layers IIL and the sacrificial layers SF stacked on top of each other. Thus, in an embodiment, when the first channel holes CHH1 are formed using the sacrificial pillars SP, a not-open failure that the first channel holes CHH1 do not completely pass through the first and second preliminary stacked structures pSTK1 and pSTK2 may be prevented or reduced.

Referring to FIG. 10C, the channel holes CHH may include the first channel holes CHH1 and second channel holes CHH2. The first channel holes CHH1 may correspond to the first channel holes CHH1 described above with reference to FIG. 10B.

The second channel holes CHH2 may be formed by a portion of the second preliminary stacked structure pSTK2 and a portion of the lower isolation structure LSP. For example, a portion of an upper surface of the lower isolation structure LSP may be exposed by removing a portion of the second preliminary stacked structure pSTK2. Subsequently, an area corresponding to the exposed portion of the lower isolation structure LSP may be etched. The areas from which the second preliminary stacked structure pSTK2 is removed and the areas from which the lower isolation structure LSP is removed may correspond to the second channel holes CHH2.

The lower isolation structure LSP might not be completely removed when the second channel holes CHH2 are formed. Therefore, the second channel holes CHH2 may pass through the lower isolation structure LSP. The lower isolation structure LSP may be located between neighboring second channel holes CHH2 in the X direction. For example, lower portions of the second channel holes CHH2 (which pass through the first preliminary stacked structure pSTK1) may contact the lower isolation structure LSP. In other words, an inner surface of the lower isolation structure LSP may be exposed through the second channel holes CHH2.

A portion of the first preliminary stacked structure pSTK1 may be etched when the second channel holes CHH2 are formed. At a predetermined level, a width of the second channel holes CHH2 in the Y direction may be greater than that of the lower isolation structure LSP in the Y direction. Therefore, an inner surface of the first preliminary stacked structure pSTK1 may be exposed through the second channel holes CHH2. However, this is a mere example. For example, the inner surface of the first preliminary stacked structure pSPK1 might not be exposed through the second channel holes CHH2. The word “predetermined” as used herein with respect to a parameter, such as a predetermined level, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

The first channel holes CHH1 and the second channel holes CHH2 may be formed simultaneously. For example, the second preliminary stacked structure pSTK2 may be partially etched to thereby expose the sacrificial pillars SP and the lower isolation structure LSP. When the exposed sacrificial pillars SP are removed, a portion of the lower isolation structure LSP may be removed together.

Compared to when the sacrificial pillars SP are not formed in the first preliminary stacked structure pSTK1, in an embodiment, defects in the second channel holes CHH2 may be reduced when the second channel holes CHH2 are formed with the lower isolation structure LSP formed in the first preliminary stacked structure pSTK1. For example, the lower isolation structure LSP may be more easily etched than the interlayer insulating layers IIL and the sacrificial layers SF stacked on top of each other. Thus, in an embodiment, when the second channel holes CHH2 are formed using the lower isolation structure LSP, a not-open failure that the second channel holes CHH2 do not completely pass through the first and second preliminary stacked structures pSTK1 and pSTK2 may be prevented or reduced.

Referring to FIG. 11, the cell plugs CPL may be formed in the channel holes CHH. The cell plugs CPL may fill the first channel holes CHH1 of FIG. 10B. However, the cell plugs CPL may fill the first channel holes CHH1 and the second channel holes CHH2 of FIG. 10C. The cell plugs CPL which are formed in the first channel holes CHH1 and the second channel holes CHH2 may have the same structure. For example, a memory layer may be formed in each of the channel holes CHH. The memory layer may contact the preliminary stacked structure pSTK. The memory layer may include the blocking layer BX, the charge trap layer CTL, and the tunnel isolation layer TX. Subsequently, the channel layer CH of FIG. 4A may be formed along an inner surface of the memory layer. Subsequently, the core pillar CO of FIG. 4A may be further formed in an area surrounded by the channel layer CH.

At least some of the cell plugs CPL may correspond to the dummy cell plug DPL. For example, in the memory device 100 according to the second embodiment, the cell plugs CPL formed in the second channel holes CHH2 may correspond to the dummy cell plugs DPL. In other words, the cell plugs CPL overlapping with the lower isolation structure LSP may correspond to the dummy cell plugs DPL.

Subsequently, trenches TR may pass through the preliminary stacked structure pSTK. A portion of the preliminary stacked structure pSTK may be etched to form the trenches TR. The trenches TR may extend in the X direction and the Z direction. Side surfaces of the interlayer insulating layers IIL and the sacrificial layers SF of the preliminary stacked structure pSTK may be exposed through the trenches TR.

According to an embodiment of the present disclosure, by complementing the processes of forming the channel holes CHH, defects of the cell plugs CPL may be reduced. In an embodiment, defects of the channel holes CHH may be reduced by the openings OP and the filling layers FL formed in the lower part (e.g., the first preliminary stacked structure pSTK1) of the preliminary stacked structure pSTK. Accordingly, in an embodiment, defects that the cell plugs CPL fail to pass through the preliminary stacked structure pSTK may be prevented or mitigated.

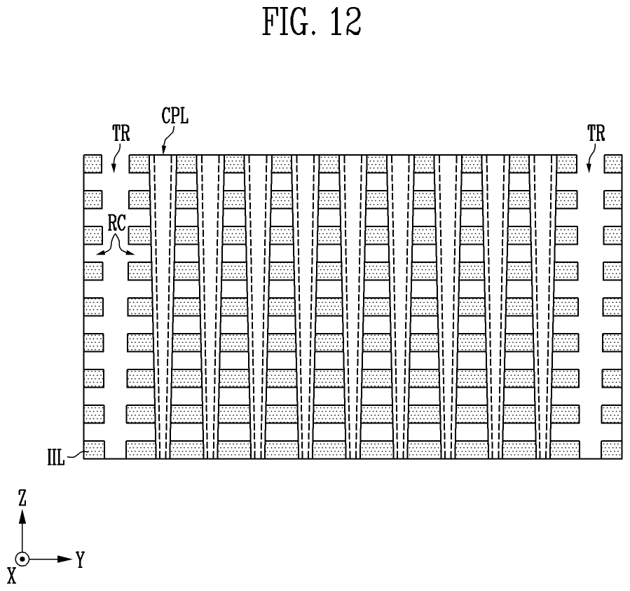

Referring to FIG. 12, the sacrificial layers SF may be removed through the trenches TR. Recesses RC may be formed in areas from which the sacrificial layers SF are removed. The recesses RC may be located between the interlayer insulating layers IIL.

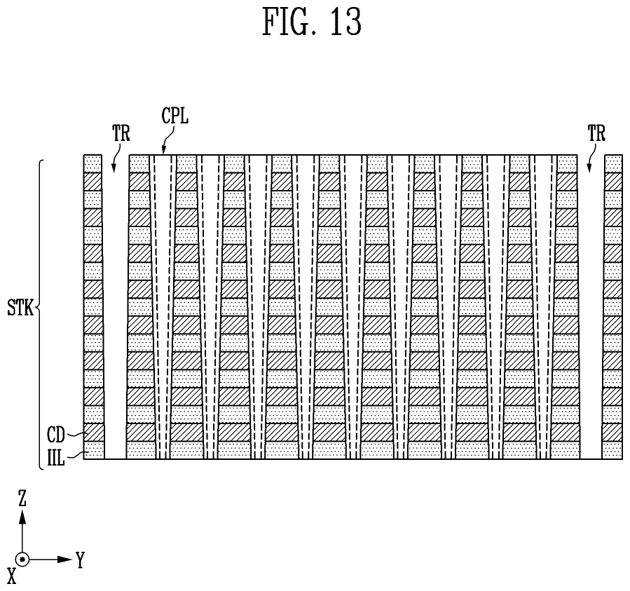

Referring to FIG. 13, the conductive layer CD may be formed in the recesses RC through the trenches TR. The conductive layers CD may be located between the interlayer insulating layers IIL. The conductive layers CD located at different layers may be insulated from each other by the interlayer insulating layers IIL. The conductive layer CD may surround the cell plugs CPL in the X and Y directions. It may be understood that the conductive layer CD and the interlayer insulating layers IIL stacked alternately with each other are included in the stacked structure STK.

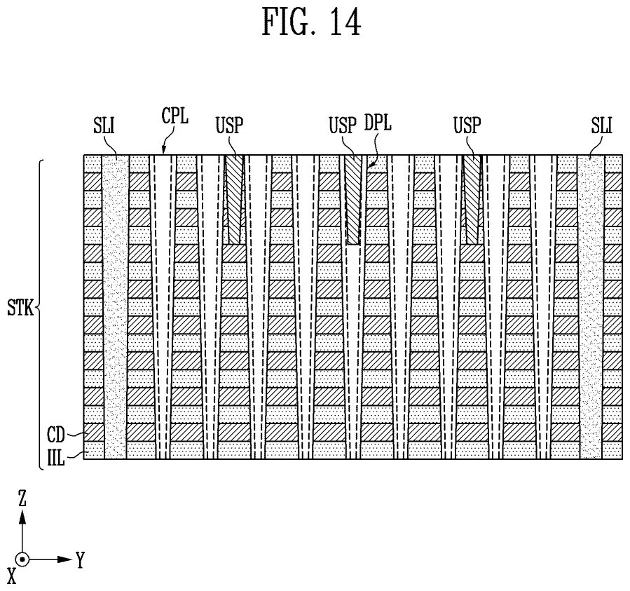

Referring to FIG. 14, the slits SLI may be formed in the trenches TR. For example, the slit SLI formed of a single layer (e.g., an insulating layer or polysilicon) or a double layer (e.g., a conductive layer surrounded by an insulating spacer) may be formed in each of the trenches TR.

Subsequently, the upper isolation structure USP may be formed in a top portion of the stacked structure STK as shown, for example, in FIG. 14. The upper isolation structure USP may pass through at least one conductive layer CD from the top among the conductive layer CD. For example, the upper isolation structure USP may pass through the drain select line DSL. In addition, the upper isolation structure USP may be located between the cell plugs CPL or overlap the cell plugs CPL. The cell plugs CPL which overlap the upper isolation structure USP may correspond to the dummy cell plugs DPL.

In an embodiment of the present disclosure, it is illustrated that the cell plugs CPL included in the stacked structure STK have a smooth curved surface. However, this is a mere example and does not limit the scope of the cell plugs CPL. For example, in some embodiments, the cell plugs CPL included in the stacked structure STK might not have a smooth curved surface. For example, the present disclosure may be applied to a double stacked structure or a triple stacked structure in which another stacked structure STK is stacked over the stacked structure STK. In an embodiment, in terms of the double stacked structure or the triple stacked structure, the filling layers FL may be previously formed in the lower part of each stacked structure STK and defects of the channel holes CHH passing through each stacked structure STK may be reduced by the filling layers FL.

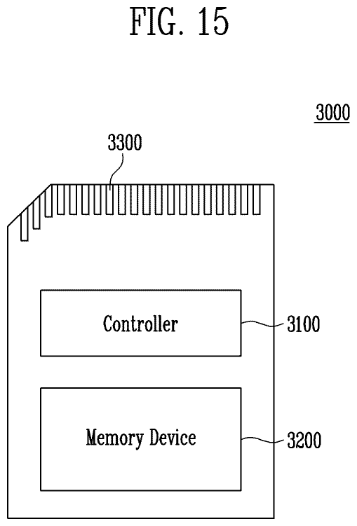

FIG. 15 is a diagram illustrating a memory card system 3000 to which a memory device according to the present disclosure is applied.

Referring to FIG. 15, the memory card system 3000 may include a controller 3100, a memory device 3200, and a connector 3300.

The controller 3100 may be coupled to the memory device 3200. The controller 3100 may access the memory device 3200. For example, the controller 3100 may control a program, read, or erase operation, or a background operation of the memory device 3200. The controller 3100 may be configured to provide an interface between the memory device 3200 and a host. The controller 3100 may be configured to drive firmware for controlling the memory device 3200. For example, the controller 3100 may include components, such as a Random Access Memory (RAM), a host interface, a memory interface, and an ECC circuit.

The controller 3100 may communicate with an external device through the connector 3300. The controller 3100 may communicate with an external device (e.g., a host) based on a specific communication protocol. For example, the controller 3100 may communicate with the external device through at least one of various communication protocols such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe) protocols. In an embodiment, the connector 3300 may be defined by at least one of the above-described various communication protocols.

The memory device 3200 may include a plurality of memory cells and be configured in the same manner as described with reference to FIG. 1.

The controller 3100 and the memory device 3200 may be integrated into a single semiconductor device to form a memory card. For example, the controller 3100 and the memory device 3200 may be integrated into a single semiconductor device to form a memory card, such as a personal computer memory card international association (PCMCIA) card, a compact flash (CF) card, a smart media card (SM, or SMC), a memory stick, a multimedia card (MMC, RS-MMC, MMCmicro, or eMMC), an SD card (SD, miniSD, microSD, or SDHC), a universal flash storage (UFS), and the like.

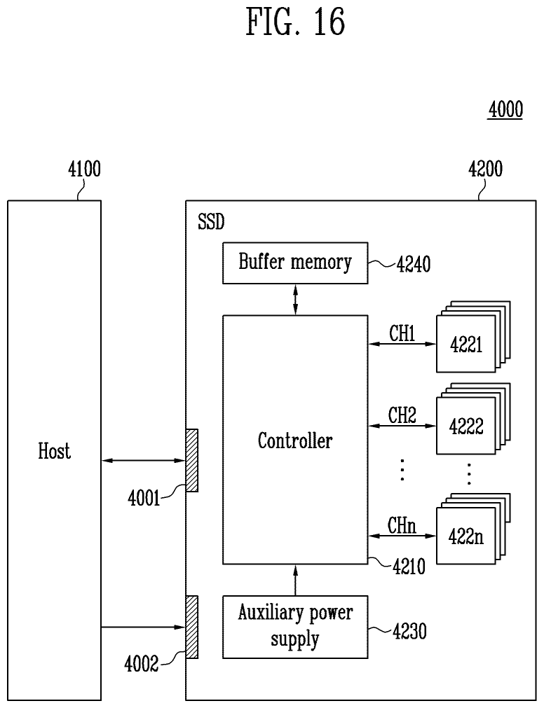

FIG. 16 is a block diagram illustrating a solid state drive (SSD) system 4000 according to an embodiment of the present disclosure.

Referring to FIG. 16, the SSD system 4000 may include a host 4100 and an SSD 4200. The SSD 4200 may exchange signals with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of

memory devices 4221 to 422n in response to the signals received from the host 4100. In an embodiment, the signals may be based on the interfaces of the host 4100 and the SSD 4200. For example, the signals may be defined by at least one of various interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), Wifi, Bluetooth, and nonvolatile memory express (NVMe) interfaces.

The plurality of memory devices 4221 to 422n may include a plurality of memory cells which are configured to store data. The plurality of memory devices 4221 to 422n may be configured in the same manner as the memory device 100 shown in FIG. 1. Therefore, the plurality of memory devices 4221 to 422n may communicate with the controller 4210 through channels CH1 to CHn.

The auxiliary power supply 4230 may be coupled to the host 4100 through the power connector 4002. The auxiliary power supply 4230 may be supplied and charged with the power from the host 4100. The auxiliary power supply 4230 may supply the power of the SSD 4200 when the power is not smoothly supplied from the host 4100. In an embodiment, the auxiliary power supply 4230 may be positioned inside or outside the SSD 4200. For example, the auxiliary power supply 4230 may be disposed in a main board and may supply auxiliary power to the SSD 4200.

The buffer memory 4240 may serve as a buffer memory of the SSD 4200. For example, the buffer memory 4240 may store data received from the host 4100 or data received from the plurality of memory devices 4221 to 422n, or may store metadata (e.g., mapping tables) of the memory devices 4221 to 422n. The buffer memory 4240 may include volatile memories such as DRAM, SDRAM, DDR SDRAM, and LPDDR SDRAM, or nonvolatile memories such as FRAM, ReRAM, STT-MRAM, and PRAM.

According to the various embodiments, defects of cell plugs may be reduced by complementing processes for forming channel holes.

It will be apparent to those skilled in the art that various modifications can be made to the above-described embodiments without departing from the spirit or scope of the disclosure. Thus, it is intended that the embodiments cover all such modifications provided they come within the scope of the appended claims and their equivalents.

What is claimed is:

1. A method of manufacturing a memory device, the method comprising:
forming first openings passing through a first preliminary stacked structure;
forming sacrificial pillars filling the first openings;
forming a second preliminary stacked structure over the first preliminary stacked structure and the sacrificial pillars;
forming first channel holes passing through the first preliminary stacked structure and the second preliminary stacked structure by removing a portion of the second preliminary stacked structure and the sacrificial pillars; and
forming cell plugs in the first channel holes.

2. The method of claim 1, wherein in the forming of the first openings, each of the first openings has substantially a shape of a hole.

3. The method of claim 1, wherein the forming of the sacrificial pillars comprises filling the first openings with an insulating material.

4. The method of claim 1, wherein the forming of the first channel holes comprises:
exposing the sacrificial pillars by etching the portion of the second preliminary stacked structure; and
removing exposed portions of the sacrificial pillars.

5. The method of claim 1, wherein in the forming of the first channel holes, the sacrificial pillars are at least partially removed to expose an inner surface of the first preliminary stacked structure through the first openings.

6. The method of claim 1, wherein in the forming of the first channel holes, each of the first channel holes has a tapered cross- section gradually decreasing toward a lower part.

7. The method of claim 1, wherein the forming of the first openings is performed simultaneously with forming a second opening passing through the first preliminary stacked structure and having substantially a linear shape.

8. The method of claim 7, wherein the forming of the sacrificial pillars is performed simultaneously with forming a lower isolation structure filling the second opening.

9. The method of claim 8, wherein the forming of the sacrificial layers and the lower isolation structure comprises filling the first openings and the second opening with an insulating material.

10. The method of claim 8, wherein the forming of the first channel holes is performed simultaneously with forming second channel holes passing through the first preliminary stacked structure and the second preliminary stacked structure by removing the portion of the second preliminary stacked structure and a portion of the lower isolation structure.

11. The method of claim 10, wherein in the forming of the first channel holes, the second channel holes pass through the lower isolation structure.

12. The method of claim 10, wherein in the forming of the second channel holes, an inner surface of the first preliminary stacked structure, an inner surface of the second preliminary stacked structure, and an inner surface of the lower isolation structure are exposed through the second channel holes.

13. The method of claim 8, wherein the forming of the first channel holes is performed simultaneously with forming second channel holes into at least a portion of the first preliminary stacked structure and passing through the second preliminary stacked structure by removing the portion of the second preliminary structure and a portion of the lower isolation structure.

14. The method of claim 13, wherein in the forming of the first channel holes, the second channel holes are formed into at least a portion of the lower isolation structure.

15. The method of claim 1, further comprising, before forming the first openings, forming the first preliminary stacked structure by stacking at least one first material layer and at least one second material layer.

16. The method of claim 15, wherein the forming of the second preliminary stacked structure comprises alternately stacking third material layers and fourth material layers over the first preliminary stacked structure,
wherein the third material layers include a same material as the first material layer, and
wherein the fourth material layers include a same material as the second material layer.

17. The method of claim 1, wherein the forming of the cell plug comprises:
forming a memory layer in each of the first holes, the memory layer contacting the first preliminary stacked structure and the second preliminary stacked structure; and
forming a channel layer on an inner surface of the memory layer.
